(19) United States
(12) Patent Application Publication
(10) Pub. No.: US 2006/0134884 A1
(43) Pub. Date: Jun. 22, 2006

(54) Wafer structure, chip structure, and fabricating process thereof

(75) Inventors: Jian Wen Lo, Banciao City (TW); Mon Chin Tsai, Kaohsiung City (TW); Tsung Hua Wu, Niaosong Township (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: ADVANCED SEMICONDUCTOR ENGINEERING, INC., Kaohsiung (TW)

(21) Appl. No.: 11/288,422

(22) Filed: Nov. 29, 2005

(30) Foreign Application Priority Data
Nov. 30, 2004 (TW) 093136831

(51) Int. Cl. H01L 21/78; H01L 21/44

(52) U.S. Cl. 438/460; 438/613

(57) ABSTRACT

A chip fabricating process with the following steps is provided. Firstly, an under ball metal (UBM) layer is formed on a plurality of bump pads and wire pads of a wafer. Then, a portion of the thickness of the UBM layer on the wire pads is removed so as to form a metal lining on the wire pads. Then, a bump is formed on the UBM layer of each bump pad. At last, the wafer is cut into a plurality of chip structures, and each chip structure includes a portion of the bump pads and the wire pads. Therefore, the present invention can fabricate the chip structure with two kinds of pads. Moreover, the present invention also discloses a chip structure and a wafer structure.

This application claims the priority benefit of Taiwan Patent Application Serial Number 093136831 filed Nov. 30, 2004, the full disclosure of which is incorporated herein by reference.

### BACKGROUND OF THE INVENTION

1. Field of the Invention

The present invention relates to a wafer structure, a chip structure and the processes for manufacturing the same, and more particularly, to a wafer structure, a chip structure made by a wire bonding technique and a flip-chip bonding technique, and the processes for manufacturing the same.

2. Description of the Related Art

With the advance in semiconductor technology in the past years, a variety of high performance electronics devices continue to be available in the market. The integration of integrated circuits (ICs) is also ever-increasing. The type of IC packaging plays an important role in packaging IC devices. The types of IC packaging substantially include the wire bonding packaging (WB packaging), tape automatic bonding packaging (TAB packaging), flip-chip packaging (FC packaging), and so on. Each of them has its own specific applications.

The chip structure, especially the pad thereof, for the wire bonding packaging technique is different from that for the flip-chip bonding packaging technique. More specifically, the flip-chip bonding packaging technique, compared to the wire bonding packaging technique, forms an under ball metal (UBM) layer including layers of metals on pads so as to enhance the bonding strength between the bumps and pads. Because the choice of pads used in a chip package depends on the process used to package the chip, the pads disposed on the chip would have to be the same type. It should be noted that if the pads disposed on chips in a multi-chip module (MCM) belong to the same type, the flexibility in designing the MCM will thus be reduced.

In view of the above, there exists a need to provide a solution to the problems mentioned above.

### SUMMARY OF THE INVENTION

It is an object of the present invention to provide a method for manufacturing chips that manufactures a chip structure with both bump pads and wire pads formed thereon.

It is another object of the present invention to provide a method for manufacturing chips that manufactures a chip structure suitable for being processed by a wire bonding process or a flip-chip bonding process subsequently.

It is a further object of the present invention to provide a chip structure that is formed by two types of pads and thus can have many practical applications.

It is a still further object of the present invention to provide a wafer structure that can be cut into three different types of chip structures.

In order to achieve the above objects and others, the present invention provides a method for manufacturing chips. Firstly, an under ball metal (UBM) layer is formed on a plurality of bump pads and wire pads of a wafer. Secondly, a portion of the thickness of the UBM layer on the wire pads is removed so as to form a metal lining. A bump is formed on the UBM layer on each of the bump pads. Then, the wafer is cut into a plurality of chip structures and each of them includes a portion of the bump pads and wire pads.

According to the preferred embodiment of the present invention, the method for forming the UBM layer is, for example, to form a UBM material layer on the wafer and then pattern the UBM material layer. In addition, the UBM material layer can be formed, for example, by sputtering.

According to the preferred embodiment of the present invention, the method for forming the bumps is, for example, to form a solder paste block on the UBM layer on each of the bump pads. Then, the wafer is processed by reflowing. In addition, the method for forming the solder paste block is, for example, by printing.

According to the preferred embodiment of the present invention, the method for forming the metal lining is, for example, to form a covering layer on the bump pads. A portion of the thickness of the UBM layer on the wire pads is removed so as to form the metal lining on the wire pads. Then, the covering layer is removed. In addition, the covering layer is, for example, made of photoresist or metal.

In order to achieve the above objects and others, the present invention provides a method for manufacturing chips. Firstly, a wafer is provided, wherein the wafer is provided with a plurality of bump pads and wire pads. Then, a covering layer is formed on the wire pads of the wafer. A UBM material layer is formed on the wafer and then the covering layer and a portion of the UBM material layer are removed, so as to form a UBM layer on the bump pads and expose the wire pads. A bump is formed on the UBM layer on each of the bump pads. Then, the wafer is cut into a plurality of chip structures and each of them includes a portion of the bump pads and wire pads.

According to the preferred embodiment of the present invention, the method for forming the covering layer is, for example, to form a covering material layer on the wafer and then pattern the covering material layer. In addition, the method for forming the covering material layer is, for example, by sputtering.

According to the preferred embodiment of the present invention, the covering layer is, for example, a nickel-vanadium/copper layer.

According to the preferred embodiment of the present invention, the covering layer is, for example, made of photoresist.

According to the preferred embodiment of the present invention, the method for forming the UBM material layer is, for example, by sputtering.

According to the preferred embodiment of the present invention, the method for forming the bumps is, for example, to form a solder paste block on the UBM layer on each of the bump pads and process the wafer by reflowing. In addition, the method for forming the solder paste blocks is, for example, by printing.

In order to achieve the above objects and others, the present invention provides a chip structure that includes a substrate, a circuit, a plurality of bump pads, a plurality of wire pads, a passivation layer, a UBM layer and a plurality of bumps, wherein the circuit is disposed on the substrate. In addition, the bump pads and wire pads are disposed on the circuit, and the passivation layer is disposed on the circuit and exposes the bump pads and wire pads. The UBM layer is disposed on the bump pads and the bumps are disposed on the UBM layer on the bump pads.

According to the preferred embodiment of the present invention, the UBM layer is, for example, an aluminum/nickel-vanadium/copper layer.

According to the preferred embodiment of the present invention, the chip structure further includes a metal lining disposed on the wire pads. In addition, the metal lining can be, for example, an aluminum layer, a gold layer or a nickel-gold layer.

In order to achieve the above objects and others, the present invention provides a chip structure that includes a substrate, a plurality of circuits, a plurality of bump pads, a plurality of wire pads, a passivation layer, a UBM layer and a plurality of bumps, wherein the substrate defines a plurality of chip areas and the circuits are disposed on the chip areas individually. In addition, the bump pads and wire pads are disposed on the circuit, and the passivation layer is disposed on the circuits and exposes the bump pads and wire pads. The UBM layer is disposed on the bump pads and the bumps are disposed on the UBM layer on the bump pads individually.

According to the preferred embodiment of the present invention, the UBM layer is, for example, an aluminum/nickel-vanadium/copper layer.

According to the preferred embodiment of the present invention, the chip structure further includes a metal lining disposed on the wire pads. In addition, the metal lining can be, for example, an aluminum layer, a gold layer or a nickel-gold layer.

According to the preferred embodiment of the present invention, both a portion of the bump pads and a portion of the wire pads are disposed on a portion of the chip areas.

According to the preferred embodiment of the present invention, a portion of the chip areas are provided with either a portion of the bump pads or a portion of the wire pads.

As mentioned above, the method for manufacturing chips according to the present invention can manufacture a chip structure with two types of pads, which can subsequently be processed by a wire bonding process or a flip-chip bonding process respectively. Accordingly, the chip structures of present invention have more applications. Furthermore, the methods for manufacturing chips according to the present invention are compatible to the existing methods.

The foregoing, as well as additional objects, features and advantages of the invention will be more readily apparent from the following detailed description of the preferred embodiments, which proceeds with reference to the accompanying drawings.

### BRIEF DESCRIPTION OF THE DRAWING

FIGS. 1A to 1F are schematic diagrams showing a method for manufacturing chips according to the first preferred embodiment of the present invention.

FIGS. 2A to 2E are schematic diagrams showing a method for manufacturing chips according to the second preferred embodiment of the present invention.

### DETAILED DESCRIPTION OF THE PREFERRED EMBODIMENT

### First Embodiment

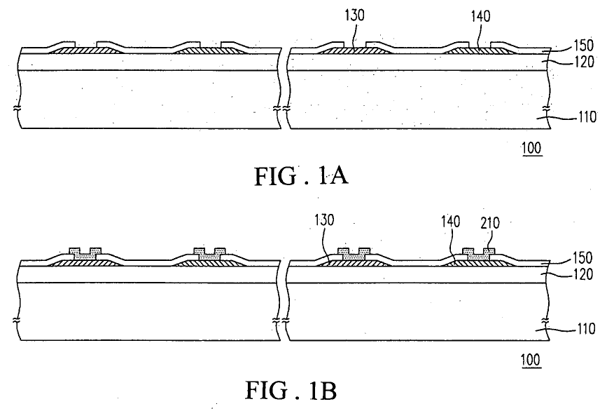

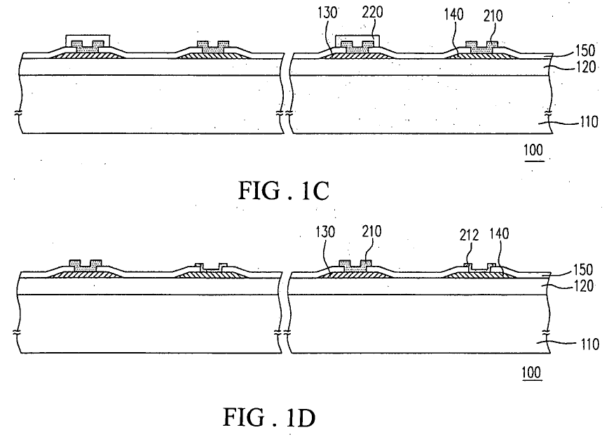

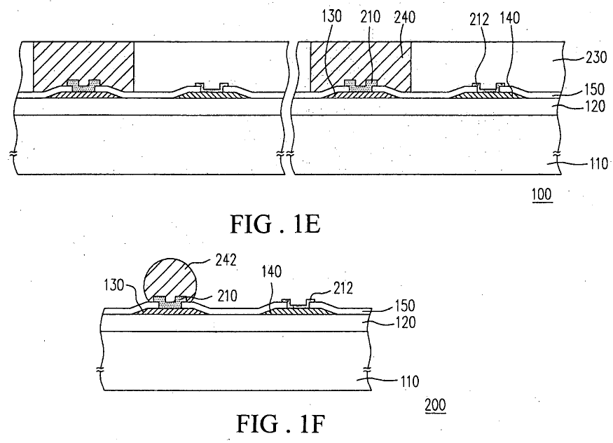

FIGS. 1A to 1F are schematic diagrams showing a method for manufacturing chips according to the first preferred embodiment of the present invention. Referring to FIG. 1A, the method for manufacturing chips of this preferred embodiment includes the following steps. Firstly, a wafer 100 is provided. The wafer 100 includes a substrate 110, a plurality of circuits 120 disposed on the substrate 110, a plurality of bump pads 130, a plurality of wire pads 140 and a passivation layer 150. The bump pads 130 and wire bumps 140 are disposed on the circuits 120. The passivation layer 150 covers the circuits 120 and exposes the bump pads 130 and wire pads 140.

Referring to FIG. 1B, an under ball metal (UBM) layer 210 is formed on the bump pads 130 and wire pads 140. The method for forming the UBM layer 210 is to form a UBM material layer on the wafer 100 (not shown in the figure) and then pattern the UBM material layer, wherein the UBM material layer can be formed by sputtering, evaporation, plating or physical vapor deposition. For example, the UBM material layer can be formed by depositing a layer of aluminum (Al), a layer of nickel-vanadium (Ni—V) and a layer of copper (Cu) in sequence on the wafer 100, wherein the layer of aluminum is at the bottom. In addition, the UBM layer 210 according to the present invention is not limited to the Al/Ni—V/Cu layer, but may be made of an Au/Ni—V/Cu layer, an Au—Ni /Ni—V//Cu layer or other multilayer metals, wherein Au is gold.

Referring to FIG. 1C, a covering layer 220 is formed on the bump pads 130 so as to protect the bump pads 130, wherein the covering layer 220 is, for example, made of photoresist or metal. As the covering layer 220 is made of photoresist, the method for forming the covering layer 220 is to coat a layer of photoresist on the bump pads 130, and then expose and develop the layer of photoresist. In contrast, if the covering layer 220 is made of metal, the method for forming the covering layer 220 is to form a layer of metal material on the bump pads 130 by sputtering and then proceed with a photolithograph process of the layer of metal and etch the layer of metal.

Referring to FIG. 1D, a portion of the thickness of the UBM layer 210 on the wire pads 140 is removed, so as to form a metal lining 212 on the wire pads 140. Then, the covering layer 220 is removed. In other words, the covering layer 220 serves as a protector and protects the UBM layer 210 on the bump pads 130 during the removal of the portion of the thickness of the UBM layer 210 on the wire pads 140. In addition, the removal of the UBM layer 210 can, for example, be achieved by etching or other processes that can remove metals. More specifically, if the UBM layer 210 is made of the Al/Ni—V/Cu layer, the metal lining 212 is made of aluminum. However, if the UBM layer 210 is made of the Au/Ni—V/Cu layer or Au—Ni /Ni—V/Cu layer, the metal lining 212 will be made of gold or gold-nickel respectively.

Referring to FIG 1E and FIG 1F, a patterned photoresist layer 230 is formed on the wafer 100 and exposes the UBM layer 210 on the bump pads 130. Secondly, a solder paste block 240 is formed on the UBM layer 210 of each of the bump pads 130. The method for forming the solder paste block 240 is, for example, by printing or other suitable processes. Then, the patterned photoresist layer 230 is removed and the wafer 100 is processed by reflowing, so as to shape the solder paste block 240 into a bump 242 (as shown in FIG. 1F). Lastly, the wafer 100 is cut into a plurality of chip structures 200, each of which includes the bump pads 130 and wire pads 140 (as shown in FIG. 1F).

It should be noted that the chip structure according to the present embodiment can provide two types of pads; therefore, a wafer can be cut into following three types of chip structures: a chip structure provided only with the bump pads 130, a chip structure provided only with the wire pads 140 and a chip structure provided with both the bump pads 130 and the wire pads 140.

Referring to FIG. 1F, a chip structure 200 includes a substrate 110, a circuit 120, a plurality of bump pads 130, a plurality of wire pads 140, a passivation layer 150, a UBM layer 210, a plurality of bumps 242 and a metal lining 212, wherein the circuit 120 is disposed on the substrate 110. The substrate 110 is made of silicon or other semiconductor material. In addition, the bump pads 130 and wire pads 140 are disposed on the circuit 120, and the passivation layer 150 is disposed on the circuit 120 and exposes the bump pads 130 and wire pads 140. The passivation layer 150 is made of silica or silicon nitride.

The UBM layer 210 is disposed on the bump pads 130 and the bumps 242 are disposed individually on the UBM layer 210 formed on the bump pads 130. In addition, the UBM layer 210 can be made of the Al/Ni—V/Cu layer, Au/Ni—V/Cu layer or Au—Ni /Ni—V/Cu layer, wherein the Al, Au and Au—Ni layers are the bottom layers respectively. Furthermore, the metal lining 212 is disposed on the wire pads 140, wherein the metal lining 212 can be made of aluminum, gold or gold-nickel. It should be noted that a bonding wire (not shown in the figure) can be formed on the metal lining 212 by a wire bonding process and the bonding wire can connect the metal lining 212 to another chip, a leadframe, a substrate or other carrier.

As mentioned above, the method for manufacturing chips according to the present invention can manufacture two types of pads that can subsequently be processed by a wire bonding process and a flip-chip bonding process respectively. Therefore, the chip structure 200 according to the present invention has more applications. It should be noted that the chip structure 200 according to the present invention has two types of pads; therefore, the chip structure 200 can be used in the chip package that is processed by the wire bonding process and the flip-chip bonding process.

### Second Embodiment

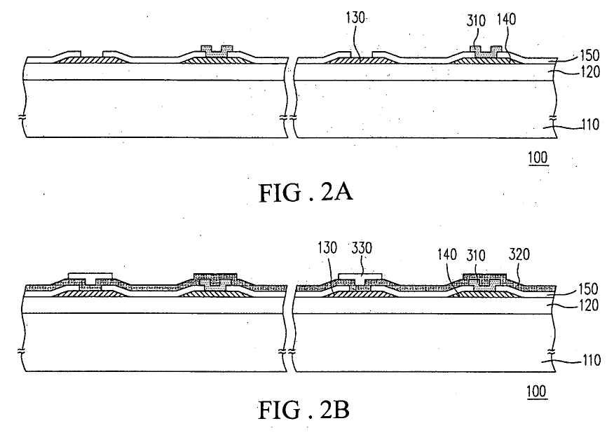

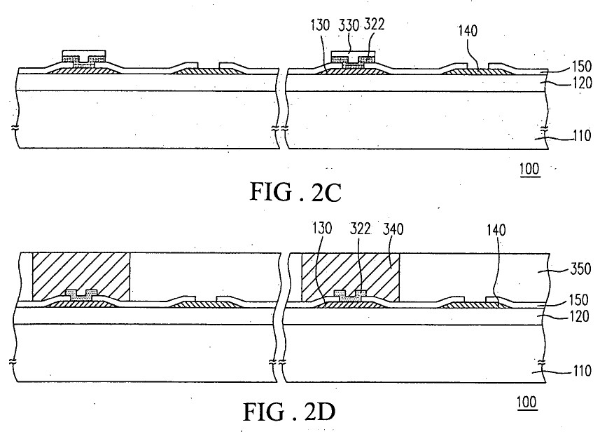

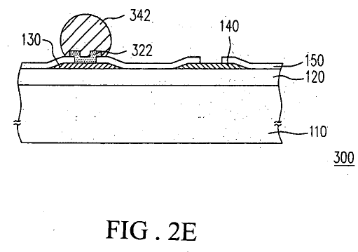

FIGS. 2A to 2E are schematic diagrams showing a method for manufacturing chips according to the second preferred embodiment of the present invention. Referring to FIG. 2A, this embodiment is similar to the first embodiment but unique in the following aspects. Firstly, a covering layer 310 is formed on the wire pads 140 of the wafer 100, wherein the covering layer310 serves as a protector and protects the wire pads 140. In addition, the covering layer 310 is made of metal or photoresist. For example, if the covering layer 310 is made of the Ni—V/Cu layer, the method for forming the Ni—V/Cu layer is by sputtering or metal deposition. In addition, the method for forming the covering layer 310 is to form a covering material layer (not shown in the figure) on the wafer 100 and then pattern the layer.

Referring to FIG. 2B, a UBM material layer 320 is formed on the wafer 100 and the method for forming the UBM material layer 320 is by sputtering or metal deposition. Then, a patterned photoresist layer 330 is formed on the UBM material layer 320. The patterned photoresist layer 330 is disposed on the bump pads 130 and thus defines an area of UBM layer322 (as shown in FIG. 2C).

Referring to FIG. 2C, the covering layer 310 and a portion of the UBM material layer 320 are removed so as to form a UBM layer 322 on the bump pads 130 and expose the wire pads 140. Then, the patterned photoresist layer 330 is removed. More specifically, the patterned photoresist layer 330 serves as a mask in the etching process of the chip structure shown in FIG. 2B; therefore, a portion of the UBM material layer 320 is removed to form the UBM layer 322. It should be noted that the method for removing the covering layer 310 depends on the material constituting the covering layer 310. If the covering layer 310 is made of metal, the method for removing the covering layer 310 is by etching. However, if the covering layer 310 is made of photoresist, the method is by a process of removing photoresist.

Referring to FIG. 2D and FIG. 2E, a patterned photoresist layer 350 is formed on the wafer 100 and exposes the UBM layer 322 on the bump pads 130. Secondly, a solder paste block 340 is formed on the UBM layer 322 of each bump pad 130. The method for forming the solder paste block 340 is by printing or other suitable processes. Then, the patterned photoresist layer 350 is removed and the wafer 100 is processed by reflowing, so as to shape the solder paste block 340 into a bump 342 (as shown in FIG. 2E). Lastly, the wafer 100 is cut into a plurality of chip structures 300, each of which includes the bump pads 130 and wire pads 140 (as shown in FIG. 2E)

Referring to FIG. 2E, the chip structures 300 are similar to the chip structures 200 except that the wire pads 140 in the chip structure 300 are exposed. It should be noted that the chip structure according to the present embodiment is provided with two types of pads; therefore, a wafer can be cut into following three types of chip structures: a chip structure provided only with the bump pads 130, a chip structure provided only with the wire pads 140 and a chip structure provided with both the bump pads 130 and the wire pads 140 (as shown in FIG. 2E). In addition, because bonding wires (not shown in the figure) are bonded directly to the wire pads 140, the bonding strength between the bonding wires and wire pads 140 is enhanced.

Therefore, the wafer structure, chip structure and the method for manufacturing the same according to the present invention have the following advantages.

1. The methods for manufacturing chips according to the present invention can manufacture a chip structure with two types of pads. Therefore, the chip structure of present invention has more applications.

2. The methods for manufacturing chips according to the present invention are compatible to the existing methods and can manufacture a chip structure with two types of pads with no need to use extra equipments.

3. The methods for manufacturing chips according the present invention can manufacture two types of pads. In other words, the methods of the present invention can form two types of pads on a wafer and then the wafer can be cut into three types of chip structures.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing chips, comprising the steps of:
providing a wafer provided with a plurality of bump pads and a plurality of wire pads thereon;
forming an under ball metal (UBM) layer on the bump pads and wire pads;
removing a portion of the thickness of the UBM layer on the wire pads so as to form a metal lining on the wire pads;
forming a bump on the UBM layer on each of the bump pads; and
cutting the wafer into a plurality of chip structures.

2. The method as claimed in claim 1, wherein the step of forming the UBM layer comprises:
forming a UBM material layer on the wafer; and
patterning the UBM material layer.

3. The method as claimed in claim 2, wherein the method for forming the UBM material layer is by sputtering.

4. The method as claimed in claim 1, wherein the step of forming the bump on the UBM layer on each of the bump pads comprises:
forming a solder paste block on the UBM layer on each of the bump pads; and
processing the wafer by reflowing.

5. The method as claimed in claim 4, wherein the method for forming the solder paste block is by printing.

6. The method as claimed in claim 1, wherein the step of forming the metal lining comprises:
forming a covering layer on the bump pads;
removing a portion of the thickness of the UBM layer on the wire pads so as to form the metal lining on the wire pads; and
removing the covering layer.

7. The method as claimed in claim 6, wherein the covering layer is made of photoresist.

8. A method for manufacturing chips, comprising the steps of:
providing a wafer provided with a plurality of bump pads and a plurality of wire pads thereon;
forming a covering layer on the bump pads of the wafer;
forming a UBM material layer on the wafer;
removing the covering layer and a portion of the UBM material layer so as to form a UBM layer on the bump pads and expose the wire pads;
forming a bump on the UBM layer on each of the bump pads; and
cutting the wafer into a plurality of chip structures.

9. The method as claimed in claim 8, wherein the step of forming the covering layer comprises:
forming a covering material layer on the wafer; and
patterning the covering material layer.

10. The method as claimed in claim 9, wherein the method for forming the covering material layer is by sputtering.

11. The method as claimed in claim 8, wherein the covering layer is a nickel-vanadium/copper layer.

12. The method as claimed in claim 8, wherein the covering layer is made of photoresist.

13. The method as claimed in claim 8, wherein the method for forming the UBM material layer is by sputtering.

14. The method as claimed in claim 8, wherein the step of forming the bump on the UBM layer on each of the bump pads comprises:
forming a solder paste block on the UBM layer on each of the bump pads; and
processing the wafer by reflowing.

15. The method as claimed in claim 14, wherein the method for forming the solder paste block is by printing.

16. The method as claimed in claim 6, wherein the covering layer is made of metal.
